(19) United States
(12) Patent Application Publication
(10) Pub. No.: US 2024/0321823 A1
(43) Pub. Date: Sep. 26, 2024

(54) SEMICONDUCTOR PACKAGE AND METHOD OF MANUFACTURING THE SAME

(71) Applicant: Samsung Electronics Co., Ltd., Suwon-si (KR)

(72) Inventors: Donguk Kwon, Suwon-si (KR); Gongmyeong Kim, Suwon-si (KR); Sunchul Kim, Suwon-si (KR); Chaein Moon, Suwon-si (KR); Hyeonrae Cho, Suwon-si (KR)

(21) Appl. No.: 18/531,883

(22) Filed: Dec. 7, 2023

(30) Foreign Application Priority Data
Mar. 24, 2023 (KR) 10-2023-0039124
Apr. 19, 2023 (KR) 10-2023-0051429

(51) Int. Cl. H01L 23/00; H01L 21/48; H01L 23/31; H01L 25/18; H10B 80/00

(52) U.S. Cl. CPC H01L 24/83; H01L 21/481; H01L 23/3128; H01L 24/13; H01L 24/16; H01L 24/32; H01L 24/73; H01L 24/81; H01L 24/92; H01L 25/18; H10B 80/00; H01L 24/48; H01L 2224/13109; H01L 2224/13111; H01L 2224/13113; H01L 2224/13116; H01L 2224/13118; H01L 2224/1312; H01L 2224/13139; H01L 2224/13144; H01L 2224/13147; H01L 2224/13155; H01L 2224/13164; H01L 2224/13169; H01L 2224/16227; H01L 2224/32237; H01L 2224/48091; H01L 2224/48227; H01L 2224/73204; H01L 2224/73265; H01L 2224/81193; H01L 2224/83102; H01L 2224/83385; H01L 2224/92125; H01L 2924/014; H01L 2924/1431; H01L 2924/1432; H01L 2924/1433; H01L 2924/1436; H01L 2924/1437; H01L 2924/1438; H01L 2924/1441; H01L 2924/1443

(57) ABSTRACT

Provided is a semiconductor package with enhanced reliability and a method of manufacturing the same. The semiconductor package includes a package substrate including a body layer having a central area and a peripheral area, a first protective layer on a top surface of the body layer, and a second protective layer on the first protective layer in the peripheral area, a semiconductor chip mounted on the first protective layer in the central area in a flip-chip structure, an underfill in a gap between the first protective layer and the semiconductor chip and in a gap between the connection terminals, an interposer on the semiconductor chip, and inter-substrate connection terminals on the peripheral area of the package substrate and electrically connecting the package substrate to the interposer, where the underfill has an anchor structure extending into the first protective layer.

### CROSS-REFERENCE TO RELATED APPLICATION

This application is based on and claims priority under 35 U.S.C. § 119 to Korean Patent Application Nos. 10-2023-0039124, filed on Mar. 24, 2023, and 10-2023-0051429, filed on Apr. 19, 2023, in the Korean Intellectual Property Office, the disclosures of which are incorporated by reference herein in their entireties.

### FIELD

The inventive concept relates to a semiconductor package, and more particularly, to a semiconductor package including an interposer and a method of manufacturing the semiconductor package.

### BACKGROUND

Due to the rapid development of the electronic industry, demand for high functionality, high speed, and miniaturization of electronic components have increased. Accordingly, a method of stacking and mounting several semiconductor chips on one package substrate or stacking a package on a package has been developed. For example, a package in package (PIP) or a package on package (POP) may be used. The POP may include an interposer for electrical connection between an upper package and a lower package. The interposer may facilitate electrical connection between the upper package and the lower package, and may reduce or prevent warpage of the upper package and the lower package.

### SUMMARY

The inventive concept provides a semiconductor package with improved reliability and a method of manufacturing the same.

In addition, the inventive concept is not limited to the above, and other inventive concepts may be clearly understood by those skilled in the art from the following description.

According to an aspect of the inventive concept, there is provided a semiconductor package which includes a package substrate including a body layer having a central area and a peripheral area adjacent the central area, a first protective layer on a top surface of the body layer, and a second protective layer on the first protective layer in the peripheral area, a semiconductor chip mounted on the first protective layer in the central area in a flip-chip structure through first connection terminals, an underfill in a gap between the first protective layer and the semiconductor chip and in a gap between the first connection terminals, an interposer on the semiconductor chip opposite the package substrate, and inter-substrate connection terminals on the peripheral area of the package substrate and electrically connecting the package substrate to the interposer, where the underfill has an anchor structure extending into the first protective layer.

According to another aspect of the inventive concept, there is provided a semiconductor package which includes a package substrate including a body layer having a central area and a peripheral area adjacent the central area, a first protective layer on a top surface of the body layer, and a second protective layer on the first protective layer in the peripheral area, a semiconductor chip mounted on the first protective layer in the central area in a flip-chip structure through first connection terminals, an underfill in a gap between the first protective layer and the semiconductor chip and in a gap between the first connection terminals, the underfill having an anchor structure extending into the first protective layer, a sealer on the package substrate and sealing the semiconductor chip and the underfill, an interposer on the semiconductor chip and the sealer opposite the package substrate, and inter-substrate connection terminals in the peripheral area of the package substrate and extending through the sealer to electrically connect the package substrate to the interposer.

According to another aspect of the inventive concept, there is provided a semiconductor package in a package on package (POP) structure, the semiconductor package including a lower package, and an upper package on the lower package, wherein the lower package includes a package substrate including a body layer having a central area and a peripheral area adjacent the central area, a first protective layer on a top surface of the body layer, and a second protective layer on the first protective layer in the peripheral area, a first semiconductor chip mounted on the first protective layer in the central area in a flip-chip structure through first connection terminals, an underfill in a gap between the first protective layer and the first semiconductor chip and in a gap between the first connection terminals and having an anchor structure extending into the first protective layer, an interposer on the first semiconductor chip opposite the package substrate, and inter-substrate connection terminals on the peripheral area of the package substrate and electrically connecting the package substrate and the interposer.

According to another aspect of the inventive concept, there is provided a method of manufacturing a semiconductor package, the method including preparing a package substrate which includes a body layer having a central area and a peripheral area adjacent the central area, a first protective layer on a top surface of the body layer, and a second protective layer on the first protective layer in the peripheral area, forming a recess in the first protective layer in the central area, mounting a semiconductor chip on the first protective layer in the central area in a flip-chip structure through connection terminals, providing an underfill in a gap between the first protective layer and the semiconductor chip, in a gap between the connection terminals, and in the recess, stacking an interposer on the semiconductor chip opposite the package substrate, and sealing the semiconductor chip by injecting a sealer between the package substrate and the interposer, where the underfill includes an anchor structure in the recess.

### BRIEF DESCRIPTION OF THE DRAWINGS

Embodiments will be more clearly understood from the following detailed description taken in conjunction with the accompanying drawings in which:

FIGS. 1A and 1B are respectively a plan view and a cross-sectional view of a semiconductor package according to an embodiment;

FIGS. 2A, 2B, 2C, 2D, 2E, and 2F are plan views of an anchor structure of an underfill in the semiconductor package of FIG. 1A;

FIGS. 3A, 3B, and 3C are cross-sectional views of an anchor structure of an underfill in the semiconductor package of FIG. 1A;

FIGS. 4A, 4B, and 4C are cross-sectional views of a semiconductor package according to some embodiments;

FIGS. 5A to 5B are cross-sectional views of a semiconductor package according to some embodiments; and

FIGS. 6A, 6B, 6C, 6D, 6E, 6F, and 6G are cross-sectional views illustrating a method of manufacturing a semiconductor package according to an embodiment.

### DETAILED DESCRIPTION OF EMBODIMENTS

Hereinafter, embodiments will be described in detail with reference to the accompanying drawings. The same reference numerals are used for the same components in the drawings, and duplicate descriptions thereof are omitted. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items.

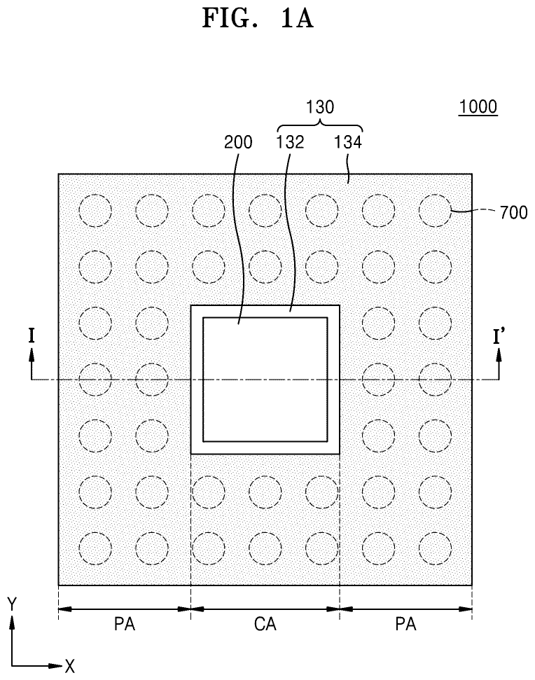

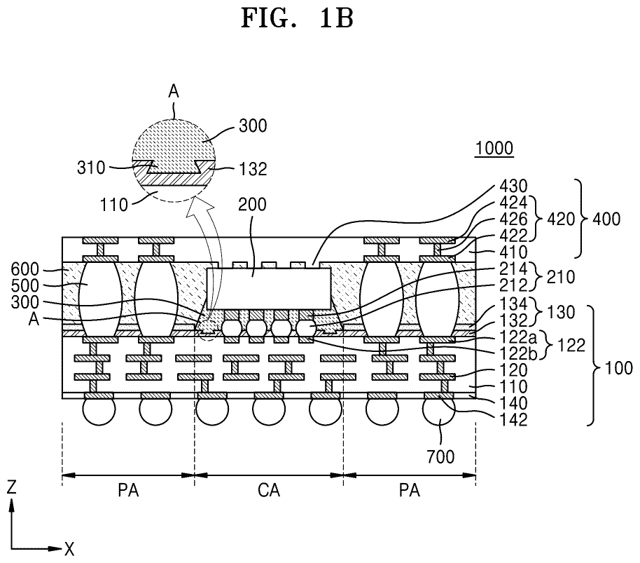

FIG. 1A is a plan view of a semiconductor package according to an embodiment, and illustrates only a package substrate and a semiconductor chip for ease of understanding. FIG. 1B is a cross-sectional view along a line I-I′ in FIG. 1A.

Referring to FIGS. 1A and 1B, a semiconductor package 1000 according to an embodiment may include a package substrate 100, a semiconductor chip 200, an underfill 300, an interposer 400, inter-substrate connection terminals 500, and a sealer 600.

The package substrate 100, which is a support substrate of the semiconductor package 1000, may include a first body layer 110, first wiring layers 120, a first upper protective layer 130, and a first lower protective layer 140.

The first body layer 110 may be formed based on, for example, a ceramic substrate, a PCB, an organic substrate, an interposer substrate, and the like. According to an embodiment, the first body layer 110 may be formed using an active wafer such as a silicon wafer. The first body layer 110 may have, for example, a thickness of about 100 micrometers (μm) to about 200 μm. However, the thickness of the first body layer 110 is not limited to the above numerical range.

The first wiring layers 120 may be arranged within the first body layer 110, and may include single-layered or multi-layered wires. In the case of the multi-layered wires, wires of different layers may be connected to each other through vertical vias. The term “connected to” may be used herein to refer to a physical and/or electrical connection. According to an embodiment, the first wiring layers 120 may include through electrodes directly connecting first upper substrate pads 122 on the top surface of the first body layer 110 to first lower substrate pads 142 on the bottom surface of the first body layer 110. As used herein, when components or layers are referred to as “directly on” or “directly connected” or in “direct contact”, no intervening components or layers are present. The first upper substrate pads 122 and the first lower substrate pads 142 may be regarded as separate components from the first wiring layers 120. However, according to an embodiment, the first upper substrate pads 122 and the first lower substrate pads 142 may be included in the first wiring layers 120. In addition, the first upper substrate pads 122 may include terminal substrate pads 122a connected to the inter-substrate connection terminals 500 and chip substrate pads 122b connected to the semiconductor chip 200.

The first upper protective layer 130 may be positioned on the top surface of the first body layer 110. The first upper protective layer 130 may include a first protective layer 132 and a second protective layer 134. The first protective layer 132 may be disposed on up to the entire top surface of the first body layer 110. The second protective layer 134 may be disposed on the first protective layer 132, and may be planarly disposed on a peripheral portion of the top surface of the first body layer 110. More specifically, on the top surface of the first body layer 110 in the x-y plane, a central area CA and a peripheral area PA surrounding the central area CA may be defined. The terms “surrounding” or “covering” or “filling” or “scaling” as may be used herein may not require completely surrounding or covering or filling or sealing the described elements or layers, but may, for example, refer to partially surrounding or covering or filling or sealing the described elements or layers. The second protective layer 134 may be positioned only in the peripheral area PA of the top surface of the first body layer 110. Accordingly, the top surface of the first protective layer 132 may be exposed in the central area CA. However, as shown in FIG. 1B, the top surface of the first protective layer 132 in the central area CA may be exposed before the semiconductor chip 200 is mounted, and may be covered by the semiconductor chip 200, the underfill 300, and the like after the semiconductor chip 200 is mounted. The term “exposed” may be used to describe relationships between elements and/or intermediate processes in fabricating a completed semiconductor device.

As shown in FIG. 1A, the semiconductor chip 200 may be arranged on the central area CA. In addition, a planar area of the central area CA may be greater than that of the semiconductor chip 200. That is, X-direction and Y-direction widths or dimensions of the central area CA may be greater than X-direction and Y-direction widths or dimensions of the semiconductor chip 200, respectively.

The first protective layer 132 and the second protective layer 134 may include the same material. For example, the first protective layer 132 and the second protective layer 134 may include solder resist (SR). However, the materials of the first protective layer 132 and the second protective layer 134 are not limited to SR. For example, according to an embodiment, the first protective layer 132 and the second protective layer 134 may include different materials, or may have different characteristics (even if they include the same material) by varying the component ratio of the constituent material(s). The first protective layer 132 and the second protective layer 134 may each have a thickness of about 10 μm to about 15 μm. However, the thicknesses of the first protective layer 132 and the second protective layer 134 are not limited to the above numerical range.

The first lower protective layer 140 may be disposed on the bottom surface of the first body layer 110. The first lower protective layer 140 may include, for example, SR. However, the material of the first lower protective layer 140 is not limited to SR. The first lower protective layer 140 may have, for example, a thickness of about 10 μm to about 15 μm. However, the thickness of the first lower protective layer 140 is not limited to the above numerical range. The first lower substrate pads 142 on the bottom surface of the first body layer 110 may be arranged in a structure penetrating or extending through the first lower protective layer 140. The bottom surfaces of the first lower substrate pads 142 may be exposed from the first lower protective layer 140, and external connection terminals 700 may be disposed on the bottom surfaces of the first lower substrate pads 142.

The semiconductor chip 200 may be mounted on or above the top surface of the package substrate 100. The semiconductor chip 200 may be, for example, a logic chip. The logic chip may include an application processor (AP), a microprocessor, a central processing unit (CPU), a controller, or an application specific integrated circuit (ASIC). The semiconductor chip 200 may have, for example, a thickness of about 50 μm to about 150 μm. However, the thickness of the semiconductor chip 200 is not limited to the above numerical range.

As shown in FIG. 1A or FIG. 1B, the semiconductor chip 200 may be positioned in the central area CA of the top surface of the package substrate 100. The semiconductor chip 200 may be mounted on or above the package substrate 100 through first connection terminals 210 and the underfill 300. Specifically, the semiconductor chip 200 may be electrically connected to the package substrate 100 through the first connection terminals 210. In addition, a gap between the semiconductor chip 200 and the package substrate 100 and a gap between the first connection terminals 210 may be filled with the underfill 300. A detailed structure of the underfill 300 is described in more detail in the description of the underfill 300 below.

The first connection terminal 210 may include solder 212 and a pillar 214. According to an embodiment, the first connection terminal 210 may include only solder. The solder 212 may have a spherical or ball shape. The solder 212 may include, for example, tin (Sn), indium (In), bismuth (Bi), antimony (Sb), copper (Cu), silver (Ag), zinc (Zn), lead (Pb), and/or or alloys thereof. For example, the solder 212 may include Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc. However, the material of the solder 212 is not limited to the above materials.

The pillar 214 may have a cylinder or a polygonal column shape such as a square column, or an octagonal column. The pillar 214 may include, for example, nickel (Ni), Cu, palladium (Pd), platinum (Pt), gold (Au), or a combination thereof. However, the material of the pillar 214 is not limited to the above materials. In the semiconductor package 1000 according to an embodiment, the pillar 214 may include, for example, Cu.

The underfill 300 may fill the gap between the semiconductor chip 200 and the package substrate 100, and the gap between the first connection terminals 210. The underfill 300 may reduce or prevent stress and strain caused by a difference in thermal expansion between the semiconductor chip 200 and the package substrate 100, and may reduce or minimize introduction of external moisture or electromagnetic influence. The underfill 300 may include a capillary underfill using capillary action, a no-flow underfill (or non-conductive paste (NCP)), a wafer level underfill (or a B-stage underfill), a molded underfill (MUF), and the like. In the semiconductor package 1000 according to an embodiment, the underfill 300 may be a capillary underfill. However, the underfill 300 is not limited to the capillary underfill. For example, various types of underfills may be used according to processes required for a semiconductor package. More specifically, in the semiconductor package 1000 according to an embodiment, the semiconductor chip 200 may be sealed through an MUF process, where the underfill 300 may include the MUF.

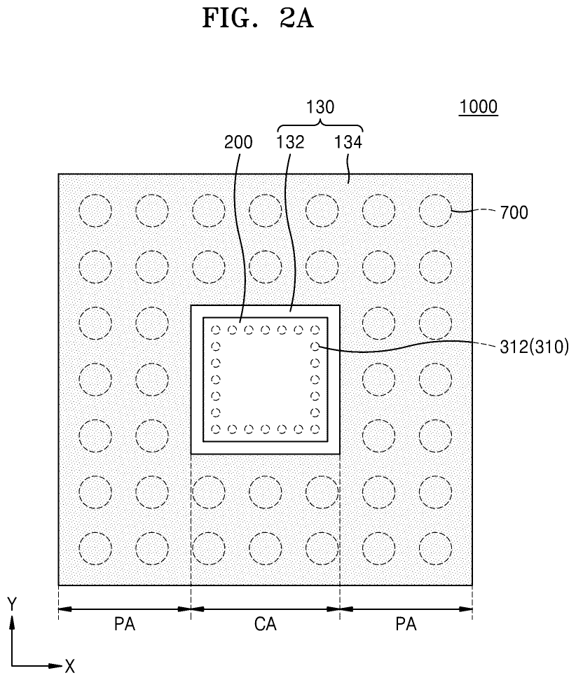

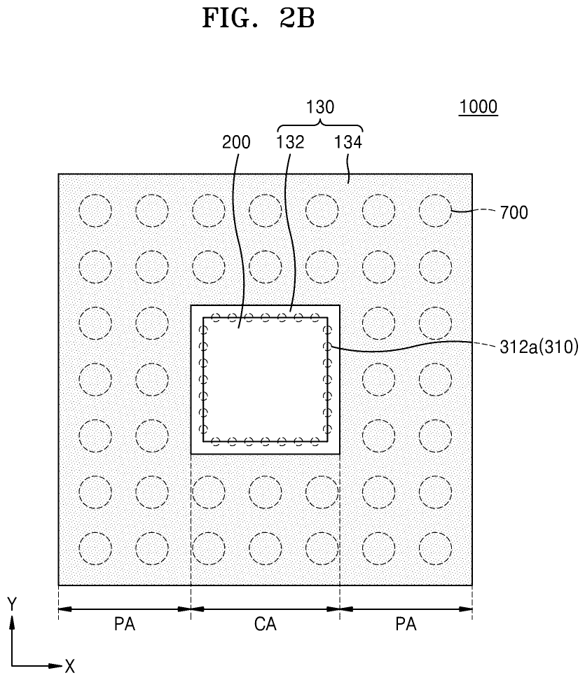

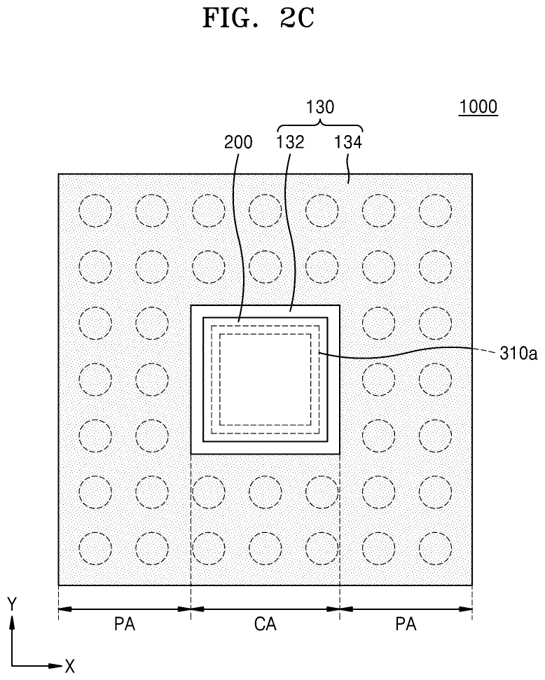

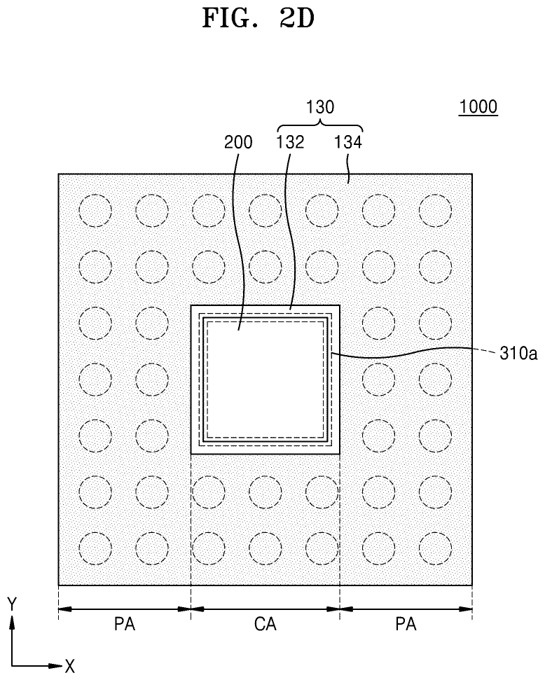

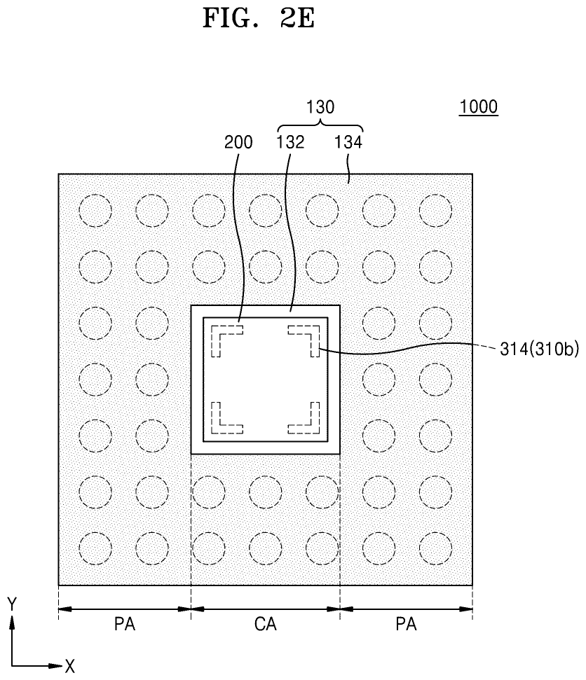

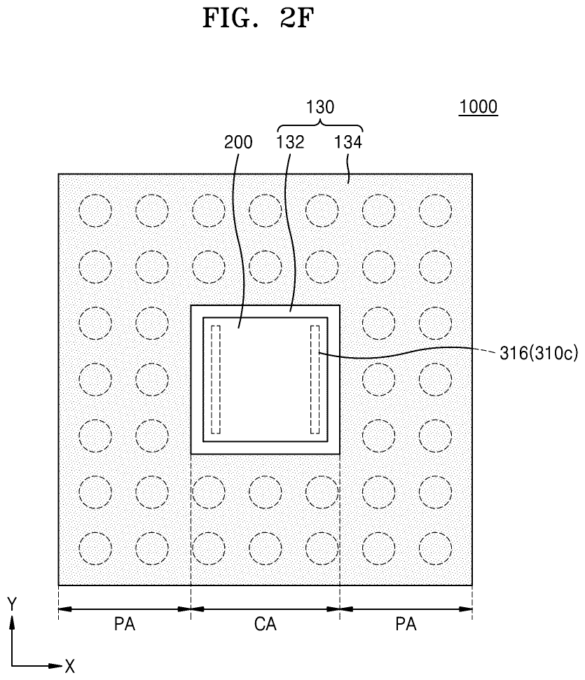

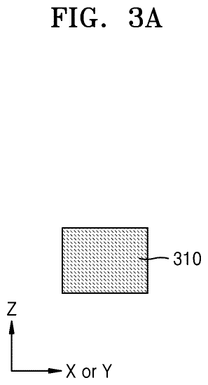

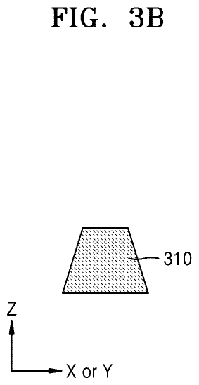

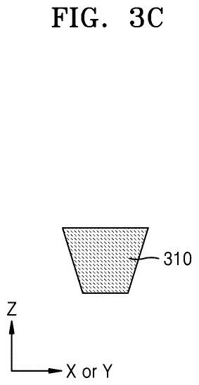

In the semiconductor package 1000 according to an embodiment, the underfill 300 may include an anchor structure 310. As can be seen from the enlarged portion of A, the anchor structure 310 of the underfill 300 may have a structure extending into and inserted into the first protective layer 132. In addition, the anchor structure 310 may be inserted into the first protective layer 132, and may be inserted only into the upper portion of (i.e., may not extend completely through) the first protective layer 132. For example, the bottom surface of the anchor structure 310 may be located in the middle of the first protective layer 132 in the Z direction, and a part of the first protective layer 132 may be positioned between the bottom surface of the anchor structure 310 and the first body layer 110. Various structures of the anchor structure 310 are described in more detail in the description of FIGS. 2A to 3C.

In the semiconductor package 1000 according to an embodiment, the underfill 300 includes the anchor structure 310 extending or inserted into the first protective layer 132 such that bonding force or adhesive strength of the underfill 300 may be enhanced by an increase in the contact surface area of the anchor structure 310 and a mechanical fastening between the underfill 300 and the first protective layer 132 provided by the anchor structure 310. Accordingly, peeling defects at the interface between the first upper protective layer 130 on the first body layer 110 (e.g., the first protective layer 132) and the underfill 300 may be effectively reduced.

For reference, after a semiconductor chip is mounted on a package substrate, torque and/or stress may be generated at the peripheral portion of the semiconductor chip due to thermal history/pressurization in a subsequent process. In addition, such torque and/or stress may cause peeling defects at the interface between an underfill and an SR layer in the peripheral portion of the semiconductor chip. For example, for a semiconductor package including an underfill without an anchor structure, the underfill has only plane-to-plane chemical bonding force with the SR layer. Therefore, peeling defects at the interface between the underfill and the SR layer may frequently occur in the peripheral portion of the semiconductor chip. In contrast, for the semiconductor package 1000 according to an embodiment, the underfill 300 includes the anchor structure 310 such that bonding force of the underfill 300 may be enhanced by an increase in the contact surface area of the anchor structure 310 and a mechanical fastening by the anchor structure 310. Thus, peeling defects at the interface between the SR layer, e.g., the first protective layer 132, and the underfill 300 may be effectively reduced or prevented.

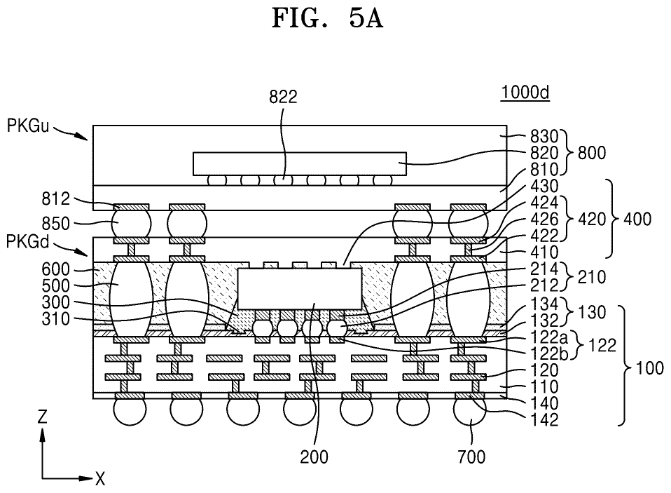

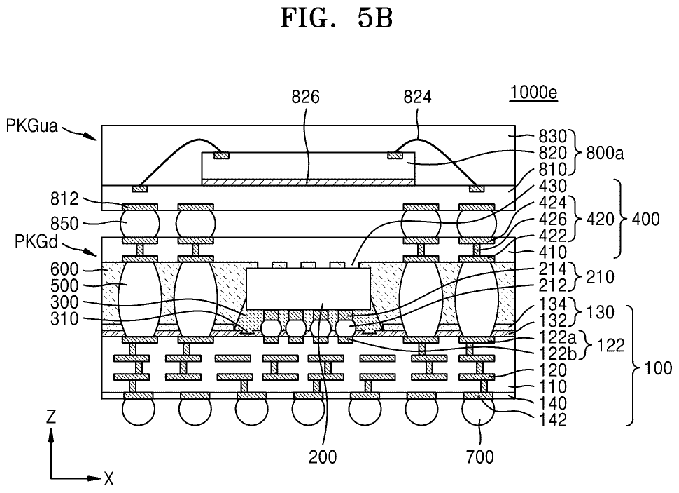

The interposer 400, which is a support substrate of an upper package (PKGu of FIG. 5A), may include a second body layer 410, second wiring layers 420, and protrusions 430. The second body layer 410 may include, for example, one of silicon, organic material, plastic, and glass. However, the material of the second body layer 410 is not limited to the above materials. When the second body layer 410 includes silicon, the interposer 400 may be referred to as a silicon interposer. In addition, when the second body layer 410 includes organic material, the interposer 400 may be referred to as a panel interposer. When the second body layer 410 includes glass, the interposer 400 may be referred to as a glass interposer. The second body layer 410 may have, for example, a thickness of about 80 μm to about 150 μm. However, the thickness of the second body layer 410 is not limited to the above numerical range.

The second wiring layers 420 may be arranged within the second body layer 410, and may include single-layered or multi-layered wires. In the case of the multi-layered wires, wires of different layers may be connected to each other through vertical vias. In the semiconductor package 1000 according to an embodiment, the second wiring layer 420 may include a lower pad 422 on the bottom surface of the second body layer 410, an upper pad 424 on the top surface of the second body layer 410, and a through electrode 426 connecting the lower pad 422 to the upper pad 424. According to an embodiment, the lower pad 422 and the upper pad 424 may be regarded as separate components from the second wiring layer 420. The inter-substrate connection terminals 500 may be disposed on the lower pads 422, and inter-package connection terminals (850 of FIG. 5A) may be disposed on the upper pads 424.

Although not shown in FIG. 1B, the interposer 400 may include protective layers on top and bottom surfaces thereof. For example, a second lower protective layer may be disposed on the bottom surface of the second body layer 410 and a second upper protective layer may be disposed on the top surface of the second body layer 410. The second lower protective layer and the second upper protective layer may include, for example, SR. However, materials of the second lower protective layer and the second upper protective layer are not limited to SR. The second lower protective layer and the second upper protective layer may have substantially the same thickness as the first lower protective layer 140 of the package substrate 100. For example, each of the second lower protective layer and the second upper protective layer may have a thickness of about 10 μm to about 15 μm. However, the thicknesses of the second lower protective layer and the second upper protective layer are not limited to the above numerical ranges.

The plurality of protrusions 430 may be disposed on the bottom surface of the second body layer 410. The protrusions 430 may be arranged at a central portion of the bottom surface of the second body layer 410 corresponding to the central area CA of the package substrate 100. The protrusions 430 may also be referred to as patches, and may include the same material, e.g., SR, as that of the second lower protective layer. However, the material of the protrusions 430 is not limited to SR. The protrusions 430 may protect the semiconductor chip 200 by buffering stress applied to the semiconductor chip 200 when the interposer 400 is stacked and bonded onto the semiconductor chip 200. In addition, the protrusions 430 may buffer stress caused by a difference in thermal expansion rate between the interposer 400 and the semiconductor chip 200. According to an embodiment, the protrusions 430 may be omitted.

In the semiconductor package 1000 according to an embodiment, the interposer 400 may be used for converting or transmitting input electrical signals between the package substrate 100 and the upper package PKGu. Accordingly, the interposer 400 may not include elements such as active elements or passive elements. The interposer 400 may have substantially the same planar area as (also referred to herein as an area corresponding to) the package substrate 100. However, according to an embodiment, the interposer 400 and the package substrate 100 may have different planar areas. For reference, a POP structure including an interposer is referred to as an interposer-POP (I-POP) structure.

According to an embodiment, a trench may be formed on a bottom surface of the interposer 400 by the second lower protective layer. The trench may correspond to the central area CA of the package substrate 100. For the interposer 400 having such a structure, an area of the trench may be substantially the same as that of the central area CA, and the semiconductor chip 200 may be positioned between the trench and the central area CA. When the trench is formed, the bottom surface of the interposer 400 may not contact the top surface of the semiconductor chip 200. Thus, stress applied to the semiconductor chip 200 in a process of stacking the interposer 400 may be reduced or removed.

The inter-substrate connection terminals 500 may be positioned between the package substrate 100 and the interposer 400. The inter-substrate connection terminals 500 may electrically connect the package substrate 100 to the interposer 400. As shown in FIGS. 1A and 1B, the inter-substrate connection terminals 500 may be arranged in the peripheral area PA of the package substrate 100 outside the semiconductor chip 200.

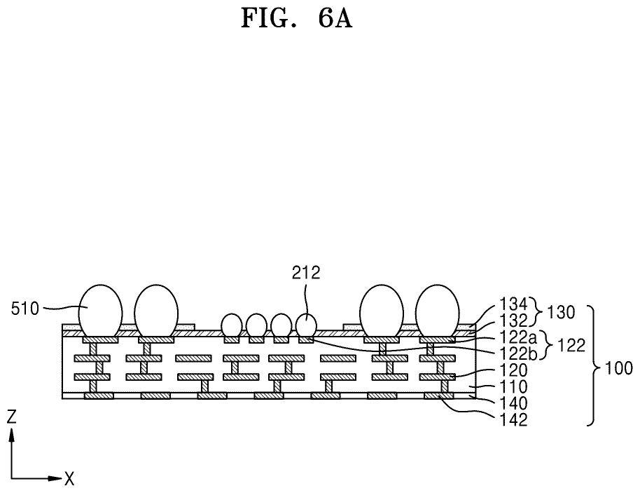

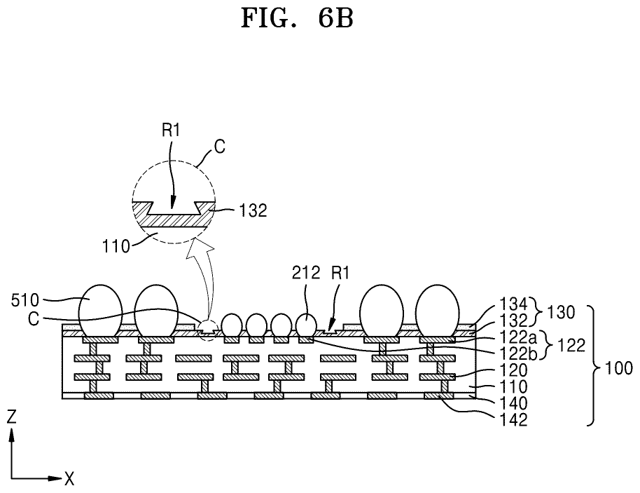

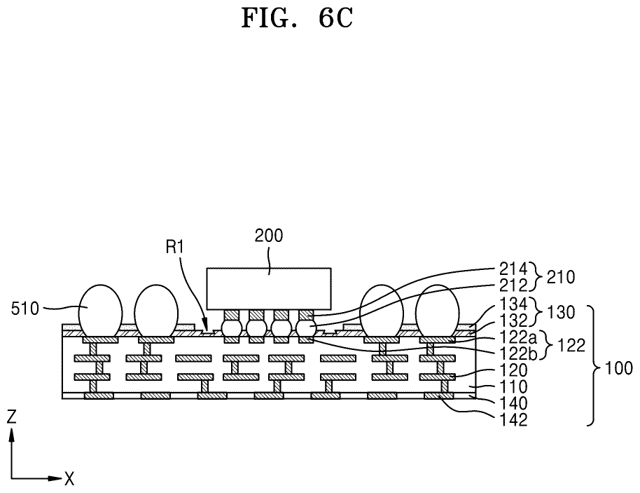

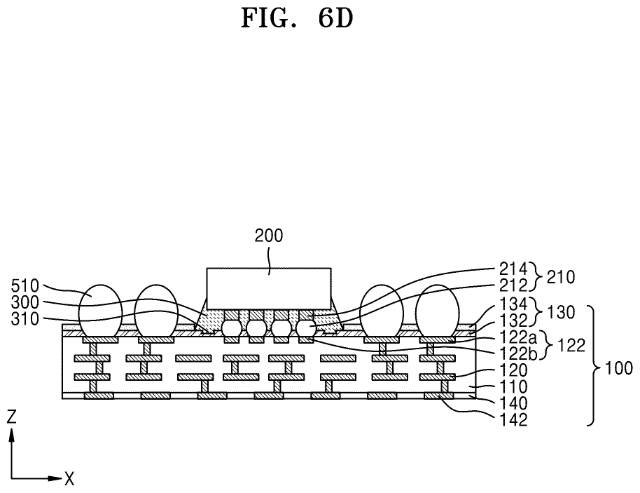

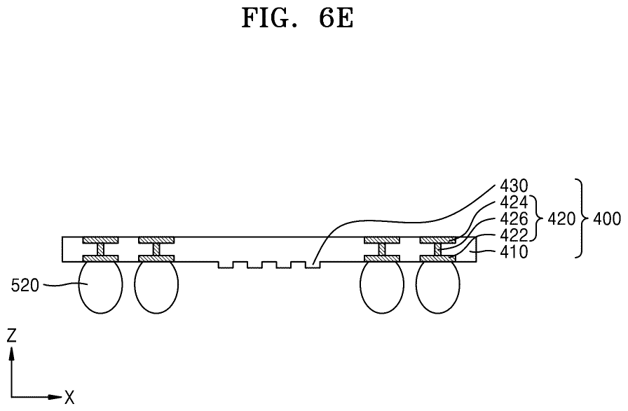

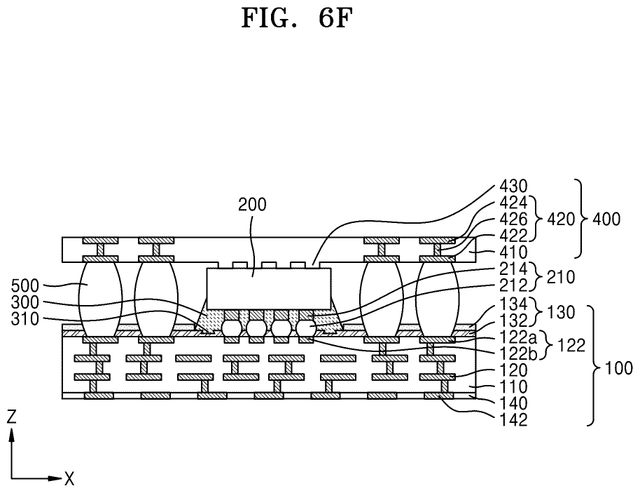

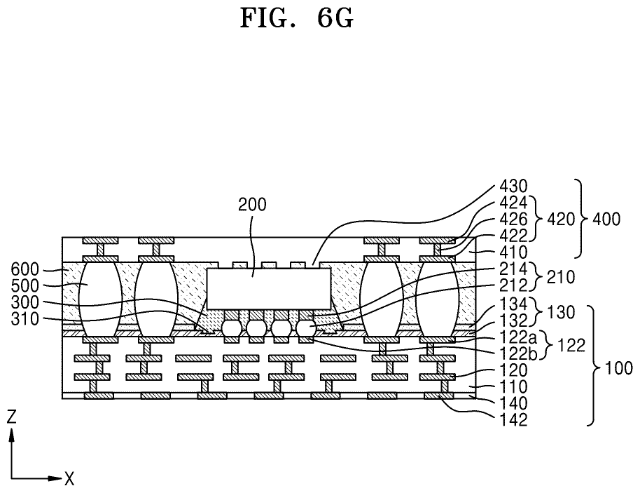

The inter-substrate connection terminals 500 may include solder. Although the inter-substrate connection terminals 500 are shown in a single-layer solder structure in FIG. 1B, but as can be seen in a method of manufacturing a semiconductor package of FIGS. 6A to 6G, the inter-substrate connection terminals 500 may include a multilayer solder structure. The material and structure of the inter-substrate connection terminals 500 may be the same as those of the solder 212 of the first connection terminals 210 described above. However, as can be seen from FIG. 1B, the inter-substrate connection terminals 500 may have a considerably greater size than the solder 212 of the first connection terminals 210.

According to an embodiment, the inter-substrate connection terminals 500 may include both solder and pillars, not just solder. When the inter-substrate connection terminals 500 include solder and pillars, the inter-substrate connection terminals 500 may have (for example) one of the following three structures: a first structure where the inter-substrate connection terminal 500 has a lower pillar and an upper solder, a second structure where the inter-substrate connection terminal 500 has a lower solder and an upper pillar, and a third structure where the inter-substrate connection terminal 500 has a lower pillar, an upper pillar, and a center solder. The material or structure of the pillar may be the same as that described for the pillar 214 of the first connection terminal 210.

The inter-substrate connection terminals 500 may extend in the Z direction and pass through the sealer 600. In addition, the inter-substrate connection terminals 500 may pass through the first upper protective layer 130 of the package substrate 100. The top surfaces of the inter-substrate connection terminals 500 may be connected to the lower pads 422 of the interposer 400, and the bottom surfaces of the inter-substrate connection terminals 500 may be connected to the first upper substrate pads 122 of the package substrate 100.

The sealer 600 may be positioned between the package substrate 100 and the interposer 400, and may seal the semiconductor chip 200. The sealer 600 may include, for example, a resin such as epoxy molding compound (EMC). However, the material of the sealer 600 is not limited to EMC. The sealer 600 may cover the top surface of the package substrate 100 and side surfaces of the semiconductor chip 200, the underfill 300, and the inter-substrate connection terminals 500. In addition, the scaler 600 may fill a gap between the interposer 400 and the semiconductor chip 200, and a gap between protrusions 430 of the interposer 400. The sealer 600 may have, for example, a thickness of about 100 μm to about 200 μm. However, the thickness of the sealer 600 is not limited to the above numerical range.

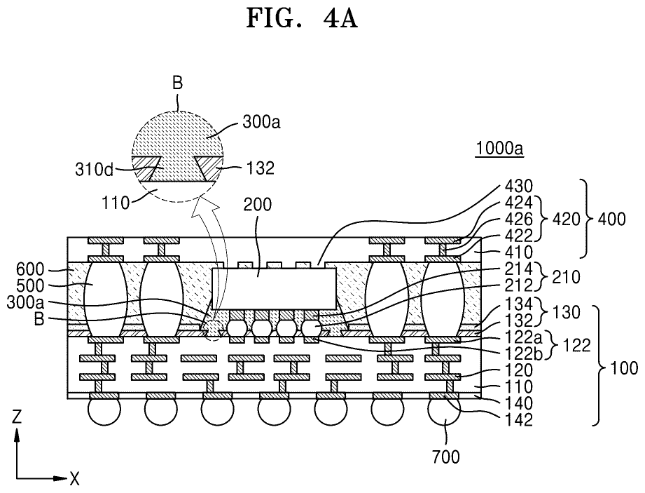

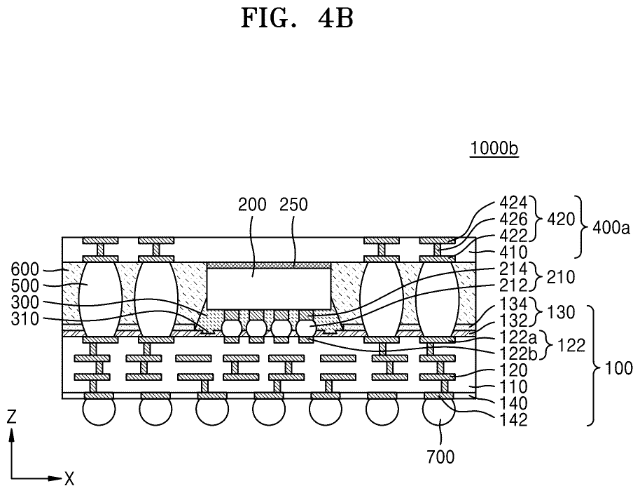

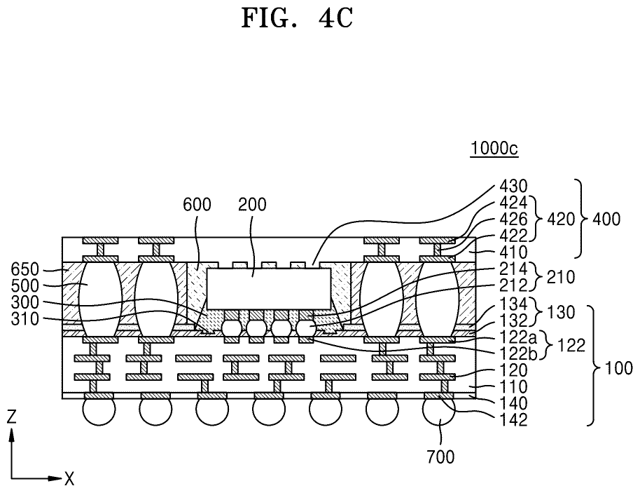

According to an embodiment, the inter-substrate connection terminals 500 may be surrounded by a filler (650 in FIG. 4C) instead of the sealer 600. The filler 650 may include a material different from that of the sealer 600. For example, the filler 650 may include non-conductive film (NCF), non-conductive paste (NCP), SR, and the like. The structure including the filler 650 may be described in more detail in the description of FIG. 4C.

The external connection terminals 700 may be arranged on the bottom surface of the package substrate 100. The external connection terminals 700 may be positioned on the first lower substrate pads 142 on the bottom surface of the first body layer 110. The external connection terminals 700 may connect the semiconductor package 1000 to a package substrate of an external system or to a main board of an electronic device such as a mobile device. The external connection terminals 700 may include conductive materials such as solder, Sn, Ag, Cu, and aluminum (Al).

In the semiconductor package 1000 according to an embodiment, the underfill 300 may include the anchor structure 310 inserted into the first protective layer 132. Accordingly, based on the increase in the contact surface area by the anchor structure 310 and the mechanical fastening by the anchor structure 310, bonding force of the underfill 300 with the first protective layer 132 may be greatly improved. Therefore, it is possible to effectively reduce or prevent peeling defects at the interface between the first protective layer 132 and the underfill 300. As a result, reliability of the semiconductor package 1000 according to an embodiment may be greatly improved based on the anchor structure 310 of the underfill 300.

FIGS. 2A to 2F are plan views of example anchor structures of an underfill in the semiconductor package of FIG. 1A, and FIGS. 3A to 3C are cross-sectional views of example anchor structures of an underfill in the semiconductor package of FIG. 1A. The elements already described with reference to FIGS. 1A and 1B are briefly described or omitted.

Referring to FIG. 2A, in the semiconductor package 1000 according to an embodiment, the anchor structure 310 of the underfill 300 may include a plurality of individual anchors 312 arranged at certain intervals along a peripheral portion of the semiconductor chip 200. As shown in FIG. 2A, when viewed from above, the anchors 312 may be arranged in an inner peripheral portion of the semiconductor chip 200, e.g., inside the perimeter or edges of the semiconductor chip 200 in plan view. Each of the anchors 312 may have a shape of one of a cylinder, a polygonal column, a truncated pyramid, and an inverted pyramid. In addition, the vertical cross section of each of the anchors 312 may have a rectangular, trapezoidal or inverted trapezoidal shape, as shown in FIGS. 3A to 3C. The vertical cross section may refer to a cross section perpendicular to the X axis or the Y axis.

Referring to FIG. 2B, in the semiconductor package 1000 according to an embodiment, similar to the anchor structure 310 of the underfill 300 of FIG. 2A, the anchor structure 310 of the underfill 300 may include a plurality of individual anchors 312a arranged at certain intervals along the peripheral portion of the semiconductor chip 200. As shown in FIG. 2B, when viewed from above, the anchors 312a may be arranged in an edge portion of the semiconductor chip 200, e.g., along the perimeter or edges of the semiconductor chip 200 in plan view. The shape or vertical cross section of the anchor 312a is the same as that of the anchor 312 of the anchor structure 310 of the underfill 300 of FIG. 2A. According to an embodiment, anchors of the anchor structure 310 may be arranged near and outside the perimeter of the semiconductor chip 200.

Referring to FIG. 2C, in the semiconductor package 1000 according to an embodiment, the anchor structure 310a of the underfill 300 may have a rectangular ring shape extending along the peripheral portion of the semiconductor chip 200. In other words, the anchor structure 310a of the underfill 300 may have a rectangular ring shape integrally connected thereto. In addition, when viewed from above, the anchor structure 310a of the underfill 300 may be arranged in the inner peripheral portion of the semiconductor chip 200, e.g., inside the perimeter or edges of the semiconductor chip 200 in plan view. A cross section of the anchor structure 310a may have a rectangular, trapezoidal or inverted trapezoidal shape as shown in FIGS. 3A to 3C. A cross section of the anchor structure 310a may refer to a cross section perpendicular to a direction in which the anchor structure 310a extends (e.g., a direction perpendicular to the X- or Y-directions).

Referring to FIG. 2D, in the semiconductor package 1000 according to an embodiment, similar to the anchor structure 310a of the underfill 300 of FIG. 2C, the anchor structure 310a of the underfill 300 may have a shape of an integrally connected square ring. As illustrated in FIG. 2D, the anchor structure 310a may be arranged at an edge portion of the semiconductor chip 200 when viewed from above, e.g., along the perimeter or edges of the semiconductor chip 200 in plan view. The cross section of the anchor structure 310a has the same shape as described for the anchor structure 310a of the underfill 300 of FIG. 2C. According to an embodiment, the anchor structure 310a may be arranged near and outside the perimeter of the semiconductor chip 200.

Referring to FIG. 2E, in the semiconductor package 1000 according to an embodiment, the anchor structure 310b of the underfill 300 may include L-shaped individual anchors 314 arranged at or adjacent four vertices of the semiconductor chip 200. In other words, each of the anchors 314 of the anchor structure 310b may extend in an L shape. In addition, when viewed from above, the anchors 314 of the anchor structure 310b may be arranged at or adjacent four vertices inside the perimeter of the semiconductor chip 200 in plan view, respectively. A cross-section of each of the anchors 314 may have a rectangular, trapezoidal, or inverted trapezoidal shape, as shown in FIGS. 3A to 3C. A cross section of the anchor 314 may refer to a cross section perpendicular to a direction in which the anchor 314 extends.

According to an embodiment, the anchors 314 may be arranged at or adjacent four vertices of the edge of the semiconductor chip 200, respectively. In addition, the anchors 314 may be arranged at four vertices near and outside the perimeter of the semiconductor chip 200 in plan view, respectively.

Referring to FIG. 2F, in the semiconductor package 1000 according to an embodiment, the anchor structure 310c of the underfill 300 may include individual anchors 316 in the form of straight lines on opposite sides of the semiconductor chip 200. In other words, the anchors 316 of the anchor structure 310c may extend in the form of straight lines on opposite sides of the semiconductor chip 200, respectively. In addition, when viewed from above, the anchors 316 of the anchor structure 310c may be arranged on opposite sides inside the perimeter of the semiconductor chip 200. A cross section of each of the anchors 316 may have a rectangular, trapezoidal or inverted trapezoidal shape, as shown in FIGS. 3A to 3C. The opposite sides of the semiconductor chip 200 may correspond to both sides where a relatively large number of peeling defects occur among left and right sides and/or upper and lower sides.

According to an embodiment, the anchors 316 may be arranged on opposite sides of the edge of the semiconductor chip 200. In addition, the anchors 316 may be arranged on opposite sides near and outside the perimeter of the semiconductor chip 200. Furthermore, the anchor structure 310c of the underfill 300 may include individual anchors 316 in the form of straight lines on four sides of the semiconductor chip 200. That is, the anchors 316 of the anchor structure 310c may extend in the form of straight lines on or along four sides of the semiconductor chip 200.

FIGS. 4A to 4C are cross-sectional views of a semiconductor package according to some embodiments. The elements already described with reference to FIGS. 1A to 3C are briefly described or omitted.

Referring to FIG. 4A, a semiconductor package 1000a according to an embodiment may be different from the semiconductor package 1000 of FIG. 1B in the anchor structure 310d of the underfill 300a. Specifically, in the semiconductor package 1000a according to an embodiment, the anchor structure 310d of the underfill 300a may have a structure penetrating or extending through the first protective layer 132, as can be seen from the enlarged portion of B. Accordingly, the bottom surface of the anchor structure 310d may be in direct contact with the top surface of the first body layer 110. In addition, the first protective layer 132 may not be positioned between the bottom surface of the anchor structure 310d and the first body layer 110. The anchor structure 310d of the underfill 300a of the semiconductor package 1000a according to an embodiment may also have various shapes and arrangements as described with reference to FIGS. 2A to 3C.

Referring to FIG. 4B, the semiconductor package 1000b according to an embodiment may be different from the semiconductor package 1000 of FIG. 1B in that the semiconductor package 1000b further includes a heat dissipation layer 250. Specifically, the semiconductor package 1000b according to an embodiment may further include the heat dissipation layer 250 between the semiconductor chip 200 and the interposer 400a. The heat dissipation layer 250 may include a metal material or a ceramic material with excellent heat dissipation performance. For example, a ceramic material with excellent heat dissipation performance may include alumina (Al₂O₃), beryllium oxide (BeO), alumina nitride (AlN), silicon carbide (SiC), boron nitride (BN), and the like. In the semiconductor package 1000b according to an embodiment, as the heat dissipation layer 250 is added to the semiconductor chip 200, the interposer 400a may not include protrusions. However, according to an embodiment, the interposer 400a may include protrusions on a bottom surface of a portion corresponding to the semiconductor chip 200.

Referring to FIG. 4C, the semiconductor package 1000c according to an embodiment may be different from the semiconductor package 1000 of FIG. 1B in that the semiconductor package 1000c includes a filler 650 around the inter-substrate connection terminals 500. Specifically, in the semiconductor package 1000c according to an embodiment, the inter-substrate connection terminals 500 may be surrounded by the filler 650 instead of the sealer 600. The semiconductor chip 200 and the underfill 300 may be surrounded by the sealer 600, and sides of the sealer 600 may be covered by the filler 650. Among both opposite sides of the package substrate 100, a part of the peripheral area PA into which the sealing material is injected may be filled with the sealer 600. That is, the sealer 600 may partially extend into the peripheral area PA.

More specifically, the filler 650 may be formed prior to the sealer 600. For example, after the package substrate 100 and the interposer 400 are completed, the filler 650 may be formed to cover the inter-substrate connection terminals (510 of FIG. 6A or 520 of FIG. 6E) of a peripheral area PA of one of the package substrate 100 and the interposer 400. For injecting the sealing material, the filler 650 may not cover a part of the peripheral areas PA on the opposite two sides among the peripheral areas PA on the four sides. Thereafter, the semiconductor chip 200 is mounted on the package substrate 100, and the interposer 400 is stacked on the package substrate 100. The first inter-substrate connection terminals 510 may be bonded to the second inter-substrate connection terminals 520, and the filler 650 may be positioned between the package substrate 100 and the interposer 400. Thereafter, the sealer 600 scaling the semiconductor chip 200 and the underfill 300 arranged in the central area CA is formed by injecting a sealing material through a part of the peripheral areas PA which are not covered by the filler 650.

The filler 650 may perform the following functions. First, the filler 650 may reduce or prevent an electrical short between the inter-substrate connection terminals 500 when the interposer 400 is stacked on the package substrate 100 through a temperature-compression bonding (TCB) process. In the TCB process, when the interposer 400 is stacked on the package substrate 100, a certain pressure is applied at a high temperature, for example, about 200° C. to about 300° C. Through this TCB process, the first inter-substrate connection terminals 510 of the package substrate 100 may be bonded to the second inter-substrate connection terminals 520 of the interposer 400 to form the inter-substrate connection terminals 500. In the TCB process, as the solder flows with fluidity due to melting and meets another adjacent solder, defects, such as short circuits, deformation, and non-wetting, may be caused. The non-wetting means that solder falls from pillars or pads, and open defects may occur due to the non-wetting. As the filler 650 is pre-arranged in the first inter-substrate connection terminals 510 or the second inter-substrate connection terminals 520, the flow of solder in the TCB process may be reduced or minimized, thereby reducing or preventing defects such as short circuits, solder deformation, non-wetting, and the like.

Second, in the process of sealing the semiconductor chip 200 by injecting the sealing material, the filler 650 may reduce or prevent defects, such as short circuits, solder deformation, non-wetting, and the like, which may occur as the sealing material passes through space between the inter-substrate connection terminals 500. Generally, in the process of injecting the scaling material, the sealing material may be maintained at a high temperature so as to be injected with fluidity. When such a high-temperature sealing material passes through space between the inter-substrate connection terminals 500, solder may flow due to melting, causing defects in the inter-substrate connection terminals 500, such as short circuits, solder deformation, or non-wetting. However, in the semiconductor package 1000c according to an embodiment, since the filler 650 fills the space between the inter-substrate connection terminals 500 in advance, the sealing material may not pass through space between the inter-substrate connection terminals 500, and thus the above defects may be reduced or prevented.

FIGS. 5A to 5B are cross-sectional views of a semiconductor package according to some embodiments. The elements already described in the description of FIGS. 1A to 4C are briefly described or omitted.

Referring to FIG. 5A, the semiconductor package 1000d according to an embodiment may be different from the semiconductor package 1000 of FIG. 1B in that the semiconductor package 1000d further includes an upper package PKGu. Specifically, the semiconductor package 1000d according to an embodiment may include the upper package PKGu and a lower package PKGd. For example, the semiconductor package 1000d according to an embodiment may have a POP structure.

The lower package PKGd may include the semiconductor package 1000 of FIG. 1B.

Accordingly, the lower package PKGd may include the package substrate 100, the semiconductor chip 200, the underfill 300, the interposer 400, the inter-substrate connection terminals 500, and the sealer 600. According to an embodiment, the lower package PKGd may include one of the semiconductor packages 1000a to 1000c of FIGS. 4A to 4C instead of the semiconductor package 1000 of FIG. 1B.

The upper package PKGu may include an upper semiconductor package 800 and inter-package connection terminals 850. The upper semiconductor package 800 may be stacked on the interposer 400 of the lower package PKGd through the inter-package connection terminals 850. For example, the top surfaces of the inter-package connection terminals 850 may be connected to second substrate pads 812 of an upper package substrate 810, and the bottom surfaces of the inter-package connection terminals 850 may be connected to upper pads 424 of the interposer 400.

The upper semiconductor package 800 may include the upper package substrate 810, an upper semiconductor chip 820, and an upper sealer 830. The upper package substrate 810, which is a wiring substrate, may have a structure similar to that of the package substrate 100 described above. The upper package substrate 810 may have a smaller size and/or thickness than the package substrate 100. According to an embodiment, the upper package substrate 810 may be formed based on an active wafer such as a silicon wafer.

The upper semiconductor chip 820 may be stacked on the upper package substrate 810 in a flip-chip bonding structure through second connection terminals 822. In FIG. 5A, the upper semiconductor chip 820 may include a single chip. However, in the semiconductor package 1000d according to an embodiment, the upper semiconductor chip 820 is not limited to a single chip. For example, the upper semiconductor chip 820 may have a stacked chip structure and include a plurality of semiconductor chips.

When the upper semiconductor chip 820 has a stacked chip structure, individual semiconductor chips may be stacked on the corresponding lower semiconductor chip through an adhesive layer. The lowermost semiconductor chip may be stacked on the upper package substrate 810 through the second connection terminals 822 and the underfill or the adhesive layer. When the upper semiconductor chip 820 has a stacked chip structure, individual semiconductor chips, except for the uppermost semiconductor chip, may include through silicon vias (TSVs) therein. Accordingly, semiconductor chips may be electrically connected to the corresponding lower semiconductor chip through TSVs and/or conductive bumps, and the lowermost semiconductor chip may be electrically connected to the upper package substrate 810 through the TSVs and the second connection terminals 822.

The upper semiconductor chip 820 may include a volatile memory semiconductor chip such as DRAM and SRAM, or may include a non-volatile memory chip such as flash memory, PRAM, MRAM, FeRAM, and RRAM. In the semiconductor package 1000d according to an embodiment, the upper semiconductor chip 820 may include, for example, a DRAM chip.

The upper sealer 830 may cover a top surface and side surfaces of the upper semiconductor chip 820 on the upper package substrate 810. In addition, when the upper semiconductor package 800 includes an underfill, the upper sealer 830 may cover side surfaces of the underfill. According to an embodiment, the upper sealer 830 may not cover the top surface of the upper semiconductor chip 820. Accordingly, the top surface of the upper semiconductor chip 820 may be exposed to the outside from the upper sealer 830. The upper scaler 830 may include, for example, EMC. However, the material of the upper sealer 830 is not limited to EMC.

Referring to FIG. 5B, a semiconductor package 1000e according to an embodiment may be different from the semiconductor package 1000d of FIG. 5A in the upper package PKGua. Specifically, the semiconductor package 1000e according to an embodiment may include a lower package PKGd and the upper package PKGua. For example, the semiconductor package 1000e according to an embodiment may have a POP structure.

The upper package PKGua may include an upper semiconductor package 800a and inter-package connection terminals 850. The upper semiconductor package 800a may be stacked on the interposer 400 of the lower package PKGd through the inter-package connection terminals 850. The upper semiconductor package 800a may include an upper package substrate 810, an upper semiconductor chip 820, and an upper sealer 830. The upper package substrate 810 is the same as the upper package substrate 810 of the upper semiconductor package 800 of the semiconductor package 1000d of FIG. 5A.

The upper semiconductor chip 820 may be stacked on the upper package substrate 810 in a wire bonding structure through an adhesive layer 826 and wires 824. In FIG. 5B, the upper semiconductor chip 820 may include a single chip. However, in the semiconductor package 1000e according to an embodiment, the upper semiconductor chip 820 is not limited to a single chip. For example, the upper semiconductor chip 820 may have a stacked chip structure and include a plurality of semiconductor chips.

When the upper semiconductor chip 820 has a stacked chip structure, individual semiconductor chips may be stacked on the corresponding lower semiconductor chip through the adhesive layer. The lowermost semiconductor chip may be stacked on the upper package substrate 810 through the adhesive layer. Each of the individual semiconductor chips may be electrically connected to the upper package substrate 810 through the wires 824. In the case of the wire bonding structure, a plurality of semiconductor chips may be stacked on the upper package substrate 810 in a stair structure or a zigzag structure to form a stacked chip structure.

FIGS. 6A to 6G are cross-sectional views illustrating a method of manufacturing a semiconductor package according to an embodiment. FIGS. 6A to 6G may be described with reference to FIG. 1B, and the elements already described with reference to FIGS. 1A to 5B are briefly described or omitted.

Referring to FIG. 6A, in the method of manufacturing a semiconductor package according to an embodiment, a package substrate 100 is prepared. The package substrate 100 may include a first body layer 110, first wiring layers 120, a first upper protective layer 130, and a first lower protective layer 140. The operation of preparing the package substrate 100 may include arranging first inter-substrate connection terminals 510 and solder 212 on the package substrate 100. The first inter-substrate connection terminals 510 may be arranged on terminal substrate pads 122a of first upper substrate pads 122, and the solder 212 (e.g., as solder bumps) may be arranged on chip substrate pads 122b of the first upper substrate pads 122.

More specifically, in the operation of preparing the package substrate 100, first, an initial package substrate where an initial upper protective layer and a first lower protective layer 140 are formed on the first body layer 110 is prepared. The initial upper protective layer may include a first protective layer 132 and an initial second protective layer. The initial second protective layer may cover the entire first protective layer 132. Thereafter, a central portion of the initial second protective layer is removed through a photo process to form the second protective layer 134. Through the formation of the second protective layer 134, a central area CA and a peripheral area PA may be defined on the package substrate 100.

Thereafter, the first inter-substrate connection terminals 510 and the solder 212 are formed on the top surface of the package substrate 100. As shown in FIG. 6A, the first inter-substrate connection terminals 510 may be formed on the terminal substrate pads 122a in a structure in which the first inter-substrate connection terminals 510 pass through the first upper protective layer 130, i.e., the first protective layer 132 and the second protective layer 134, and upper portions thereof protrude therefrom. In addition, the solder 212 may be formed on the chip substrate pads 122b in a structure in which the solder 212 (e.g., the solder bumps) pass through the first protective layer 132 and upper portions thereof protrude therefrom.

Referring to FIG. 6B, after preparing the package substrate 100, a recess R1 for an anchor structure is formed in the first protective layer 132 of the central area CA. As can be seen from the enlarged portion of C, the recess R1 may be formed by etching an upper portion of the first protective layer 132. The recess R1 may have various shapes and arrangement structures, and the anchor structure having various shapes and arrangement structures illustrated in FIGS. 2A to 3C may be formed according to the shape of the recess R1. For example, the recess R1 may include individual grooves to form a plurality of individual anchors 312 and 312a of the anchor structure 310 of FIG. 2A or 2B. In addition, the recess R1 may have a structure in which at least a portion thereof extends along the peripheral portion of the semiconductor chip 200 to form the anchor structures 310a, 310b, and 310c of FIGS. 2C to 2F.

According to an embodiment, the recess R1 may be formed in a structure penetrating or extending through the entire first protective layer 132. When the recess R1 has a structure penetrating or extending through the entire first protective layer 132, the anchor structure 310d of the underfill 300a of the semiconductor package 1000a of FIG. 4A may be implemented.

Referring to FIG. 6C, after forming the recess R1 for the anchor structure in the first protective layer 132, the semiconductor chip 200 is mounted in the central area CA of the package substrate 100. The semiconductor chip 200 may be mounted on the package substrate 100 through the first connection terminals 210. For example, the semiconductor chip 200 may be mounted on the substrate package 100 as the pillars 214 are disposed on the bottom surface of the semiconductor chip 200 and are bonded to the solder 212. Accordingly, the first connection terminals 210 may include the solder 212 (e.g., the solder bumps) and the pillars 214.

Referring to FIG. 6D, after mounting the semiconductor chip 200 through the first connection terminals 210, the underfill 300 is formed between the semiconductor chip 200 and the package substrate 100 through an underfill process. In the method of manufacturing the semiconductor package according to an embodiment, the underfill 300 may include capillary underfill. Accordingly, the underfill 300 may be formed using capillary action. However, the underfill 300 is not limited to the capillary underfill. For example, the underfill 300 may include MUF. In such a case, the underfill 300 may be formed through a MUF process. In addition, the underfill 300 and the sealer 600 may not be distinguished. That is, a same material may be used for both the underfill 300 and the sealer 600 in some embodiments. In the underfill process, the underfill 300 may fill the recess R1. Accordingly, the underfill 300 may include the anchor structure 310 at a portion corresponding to the recess R1. The anchor structure 310 may have various shapes and arrangement structures according to the shapes and arrangement structures of the recess R1.

Referring to FIG. 6E, the interposer 400 is prepared. The interposer 400 may include a second body layer 410, second wiring layers 420, and protrusions 430. The operation of preparing the interposer 400 may include disposing the second inter-substrate connection terminals 520 on the bottom surface of the interposer 400. The second inter-substrate connection terminals 520 may be disposed on the lower pads 422 of the second wiring layers 420. The operation of preparing the interposer 400 may be performed simultaneously with preparing the package substrate 100, or may be performed before preparing the package substrate 100. In addition, the operation of preparing the interposer 400 may be performed while forming the recess R1 in FIG. 6B or while forming the underfill 300 in FIG. 6D.

Referring to FIG. 6F, after preparing the interposer 400, the interposer 400 is stacked on the semiconductor chip 200. A process of stacking the interposer 400 may be performed through a TCB process. In the process of stacking the interposer 400, the first inter-substrate connection terminals 510 may be bonded to the second inter-substrate connection terminals 520 to form the inter-substrate connection terminals 500. The protrusions 430 of the interposer 400 may contact the top surface of the semiconductor chip 200.

Referring to FIG. 6G, after the interposer 400 is stacked, a sealing material, e.g., EMC, is injected between the package substrate 100 and the interposer 400 to form the sealer 600. The sealer 600 may cover the side surfaces of the semiconductor chip 200 and the underfill 300 to seal the semiconductor chip 200. In addition, the sealer 600 may fill a gap between the semiconductor chip 200 and the interposer 400 and gaps between the protrusions 430. Thereafter, the semiconductor package 1000 of FIG. 1B may be completed by forming the external connection terminals 700 on the bottom surface of the package substrate 100.

The semiconductor package 1000d of FIG. 5A or the semiconductor package 1000e of FIG. 5B may be completed by stacking the upper semiconductor package 800 or 800a on the interposer 400 through the inter-package connection terminals 850 before forming the external connection terminals 700, and then forming the external connection terminals 700 on the bottom surface of the package substrate 100. In addition, the semiconductor package 1000c of FIG. 4C may be completed by forming the filler 650 in a peripheral portion of the package substrate 100 or the interposer 400 before stacking the interposer 400, and then performing a process of stacking the interposer 400 and a process of forming the sealer 600.

While the inventive concept has been particularly shown and described with reference to embodiments thereof, it will be understood that various changes in form and details may be made therein without departing from the scope of the following claims.

1. A semiconductor package comprising:
a package substrate including a body layer having a central area and a peripheral area adjacent the central area, a first protective layer on a top surface of the body layer, and a second protective layer on the first protective layer in the peripheral area;
a semiconductor chip mounted on the first protective layer in the central area in a flip-chip structure through first connection terminals;
an underfill in a gap between the first protective layer and the semiconductor chip, and in a gap between the first connection terminals;
an interposer on the semiconductor chip opposite the package substrate; and
inter-substrate connection terminals in the peripheral area of the package substrate and electrically connecting the package substrate to the interposer;
wherein the underfill has an anchor structure extending into the first protective layer.

2. The semiconductor package of claim 1,
wherein the anchor structure is positioned along a peripheral portion of the semiconductor chip.

3. The semiconductor package of claim 2,
wherein the anchor structure comprises a plurality of anchors arranged at intervals along the peripheral portion of the semiconductor chip.

4. The semiconductor package of claim 3,
wherein each of the anchors has a shape of a cylinder, a polygonal column, a truncated pyramid, or an inverted pyramid.

5. The semiconductor package of claim 2,
wherein the semiconductor chip has a rectangular shape, and
the anchor structure has a rectangular ring shape extending along the peripheral portion of the semiconductor chip.

6. The semiconductor package of claim 5,
wherein a cross section of the anchor structure, perpendicular to a direction in which the rectangular ring shape extends, has a shape of a rectangle, a trapezoid, or an inverted trapezoid.

7. The semiconductor package of claim 1,
wherein the anchor structure extends into an upper portion of the first protective layer, and
a part of the first protective layer is between the anchor structure and the body layer.

8. The semiconductor package of claim 7,
wherein the inter-substrate connection terminals extend through the second protective layer and the first protective layer and are electrically connected to terminal substrate pads on the body layer, and
the first connection terminals extend through the first protective layer and are electrically connected to chip substrate pads on the body layer.

9. The semiconductor package of claim 8,
wherein the first connection terminals respectively comprises a solder bump and a pillar,
wherein the solder bumps extend through the first protective layer and are connected to the chip substrate pads and upper portions thereof protrude from the first protective layer, and
the underfill extend on the upper portions of the solder bumps and on side surfaces of the pillars.

10. The semiconductor package of claim 1,
wherein the interposer comprises protrusions on a bottom surface of an area corresponding to the central area, and
the protrusions are in contact with a top surface of the semiconductor chip.

11. A semiconductor package comprising:
a package substrate including a body layer having a central area and a peripheral area adjacent the central area, a first protective layer on a top surface of the body layer, and a second protective layer on the first protective layer in the peripheral area;
a semiconductor chip mounted on the first protective layer in the central area in a flip-chip structure through first connection terminals;
an underfill in a gap between the first protective layer and the semiconductor chip, and in a gap between the first connection terminals, the underfill having an anchor structure extending into the first protective layer;
a sealer on the package substrate and sealing the semiconductor chip and the underfill;
an interposer on the semiconductor chip and the sealer opposite the package substrate; and
inter-substrate connection terminals in the peripheral area of the package substrate and extending through the sealer to electrically connect the package substrate to the interposer.

12. The semiconductor package of claim 11,
wherein the anchor structure comprises a plurality of anchors arranged at intervals along a peripheral portion of the semiconductor chip.

13. The semiconductor package of claim 11,
wherein the semiconductor chip has a rectangular shape, and
the anchor structure has a rectangular ring shape extending along a peripheral portion of the semiconductor chip.

14. The semiconductor package of claim 11,
wherein the anchor structure extends into an upper portion of the first protective layer, and
a portion of the first protective layer is between the anchor structure and the body layer.

15. The semiconductor package of claim 14,
wherein the inter-substrate connection terminals extend through the second protective layer and the first protective layer and are electrically connected to terminal substrate pads on the body layer, and
the first connection terminals extend through the first protective layer and are electrically connected to chip substrate pads on the body layer.

16. A semiconductor package in a package on package (POP) structure, the semiconductor package comprising:
a lower package; and
an upper package on the lower package;
wherein the lower package comprises
a package substrate including a body layer having a central area and a peripheral area adjacent the central area, a first protective layer on a top surface of the body layer, and a second protective layer on the first protective layer in the peripheral area,
a first semiconductor chip mounted on the first protective layer in the central area in a flip-chip structure through first connection terminals,
an underfill in a gap between the first protective layer and the first semiconductor chip, and in a gap between the first connection terminals, the underfill having an anchor structure extending into the first protective layer,
an interposer on the first semiconductor chip opposite the package substrate, and
inter-substrate connection terminals on the peripheral area of the package substrate and electrically connecting the package substrate and the interposer.

17. The semiconductor package of claim 16,
wherein the first semiconductor chip has a rectangular shape, and
wherein the anchor structure comprises a plurality of anchors arranged at intervals along a peripheral portion of the first semiconductor chip, or the anchor structure has a rectangular ring shape extending along the peripheral portion of the first semiconductor chip.

18. The semiconductor package of claim 16,
wherein the anchor structure extends into an upper portion of the first protective layer, and
a part of the first protective layer is between the anchor structure and the body layer.

19. The semiconductor package of claim 16,
wherein the upper package is stacked on the lower package through inter-package connection terminals, and the upper package comprises at least one second semiconductor chip.

20. The semiconductor package of claim 19,
wherein the first semiconductor chip comprises a logic chip, and
the at least one second semiconductor chip comprises a memory chip.

21.-25. (canceled)
